(19) United States
(12) Patent Application Publication
(10) Pub. No.: US 2007/0006058 A1
(43) Pub. Date: Jan. 4, 2007

(54) Path metric computation unit for use in a data detector

(75) Inventor: Chandra C. Varanasi, Longmont, CO (US)

Correspondence Address: SEAGATE TECHNOLOGY LLC C/O WESTMAN;CHAMPLIN & KELLY, P.A., SUITE 1400, 900 SECOND AVENUE SOUTH, MINNEAPOLIS, MN, 55402-3319, US

(73) Assignee: Seagate Technology LLC, Scotts Valley, CA (US)

(21) Appl. No.: 11/171,599

(22) Filed: Jun. 30, 2005

(51) Int. Cl. H03M 13/15

(52) U.S. Cl. 714/795

(57) ABSTRACT

A data detector for use in a communication channel is provided. The data detector includes a path metric unit, which is configured to operate at a rate of at least two samples per clock cycle. The path metric unit includes multiple add units and multiple compare units. In the determination of a lowest path-metric among multiple paths that reach a state, at least one of the multiple add units of the path metric unit operates in parallel with at least one of its multiple compare units, thereby reducing a critical path in the path metric unit.

### FIELD OF THE INVENTION

The present invention relates generally to communication channels, and more particularly but not by limitation to read/write channels in data storage devices.

### BACKGROUND OF THE INVENTION

Data communication channels generally include encoding of data before it passes through a communication medium, and decoding of data after it has passed through a communication medium. Data encoding and decoding are used, for example, in data storage devices for encoding data that is written on a storage medium and decoding data that is read from a storage medium. Encoding is applied in order to convert the data into a form that is compatible with the characteristics of the communication medium, and can include processes such as adding error correction codes, interleaving, turbo encoding, bandwidth limiting, amplification and many other known encoding processes. Decoding processes are generally inverse functions of the encoding processes. Encoding and decoding increases the reliability of the reproduced data.

Decoding using a Viterbi algorithm and other Viterbi-like algorithms, such as a soft output Viterbi algorithm (SOVA), are known. In general, such algorithms can be viewed as dynamic programming algorithms for finding the shortest path through a trellis. A Viterbi decoder (a processor that implements the Viterbi algorithm or Viterbi-like algorithm) calculates what are referred to as metrics to determine that path in the trellis (or trellis diagram) which has a greatest or smallest path metric depending on the respective configuration of the decoder. The decoded sequence can then be determined and emitted, on the basis of this path in the trellis diagram.

In a typical trellis diagram on which data decoding is based, each data symbol sequence is allocated a corresponding path. Each branch in the trellis diagram symbolizes a state transition between two successive states in time, and a path includes a sequence of branches between two successive states in time.

As mentioned above, the Viterbi decoder uses the trellis diagram to determine that path which has the best path metric. A typical configuration of a Viterbi decoder includes a branch metric unit, a path metric unit and a survivor path decoding unit. The object of the branch metric unit is to calculate the branch metrics, which are a measure of the difference between a received symbol and that symbol which causes the corresponding state transition in the trellis diagram. The branch metrics calculated by the branch metric unit are supplied to the path metric unit in order to determine the optimum paths (survivor paths), with a survivor memory unit typically storing these survivor paths so that, in the end, decoding can be carried out by the survivor path decoding unit on the basis of that survivor path which has the best path metric. The symbol sequence associated with this path has the highest probability of corresponding with the actually transmitted sequence.

The path metric unit of a Viterbi detector recursively computes the shortest paths to time n, in terms of the shortest paths to time n+1. Such recursive computations are complex and therefore, in a Viterbi detector, the path metric unit is the module that consumes the most power and area. Viterbi detectors are used in data storage device read channels with throughputs over 1 GHz. But at these high speeds, area and power are still limited.

In general, conventional Viterbi detector path metric units or circuits have been based on radix-2 trellises. In a radix-2 trellis, for each state of the trellis, there are two input branches and, in radix-2 or two-way path metric units, one symbol is decoded at each clock cycle. Some more recent path metric calculation circuits are based on a radix-4 trellis structure (four input branches for each trellis state), which essentially combines two iterations of a radix-2 trellis into one iteration. In a radix-4 or four-way path metric circuit, two symbols are decoded at each clock cycle instead of one. In general, as compared to a radix-2 path metric circuit, radix-4 path metric circuits are potentially less power consuming and provide higher throughputs. However, in existing radix-4 path metric circuits, arithmetic operations (such as add, compare and select operations) are generally sequential in nature, which can lead to processing bottlenecks.

Embodiments of the present invention provide solutions to these and other problems, and offer other advantages over the prior art.

### SUMMARY OF THE INVENTION

A data detector for use in a communication channel is provided. The data detector includes a path metric unit, which is configured to operate at a rate of at least two samples per clock cycle. The path metric unit includes multiple add units and multiple compare units. In the determination of a lowest path-metric among multiple paths that reach a state, at least one of the multiple add units of the path metric unit operates in parallel with at least one of its multiple compare units, thereby reducing a critical path in the path metric unit.

Other features and benefits that characterize embodiments of the present invention will be apparent upon reading the following detailed description and review of the associated drawings.

### BRIEF DESCRIPTION OF THE DRAWINGS

FIG. 1 is an isometric view of a disc drive.

FIG. 2 illustrates a block diagram of a channel.

FIG. 3 is a diagrammatic illustration of a typical state transition in a radix-4 n-state Viterbi trellis.

FIG. 4 is a diagrammatic illustration of a critical path in a path metric computation unit in which arithmetic operations take place sequentially.

FIGS. 5 and 6 are diagrammatic illustrations of critical paths in path metric units in which at least some arithmetic operations take place in parallel.

FIG. 7 is a diagrammatic illustration of a building block of a radix-4 data-dependent-noise-predictive (DDNP) soft output Viterbi algorithm (SOVA) trellis.

### DETAILED DESCRIPTION OF ILLUSTRATIVE EMBODIMENTS

In the embodiments described below, a Viterbi detector includes a path metric unit that has multiple add units and multiple compare units. In the determination of a lowest path-metric among multiple paths that reach a state, at least one of the add units of the path metric unit operates in parallel (substantially concurrently) with at least one of its compare units, thereby reducing a critical path in the path metric unit. A critical path in a path metric unit of a Viterbi detector is a time period that the path metric unit takes to carry out arithmetic operations necessary to update a path-metric value of a state.

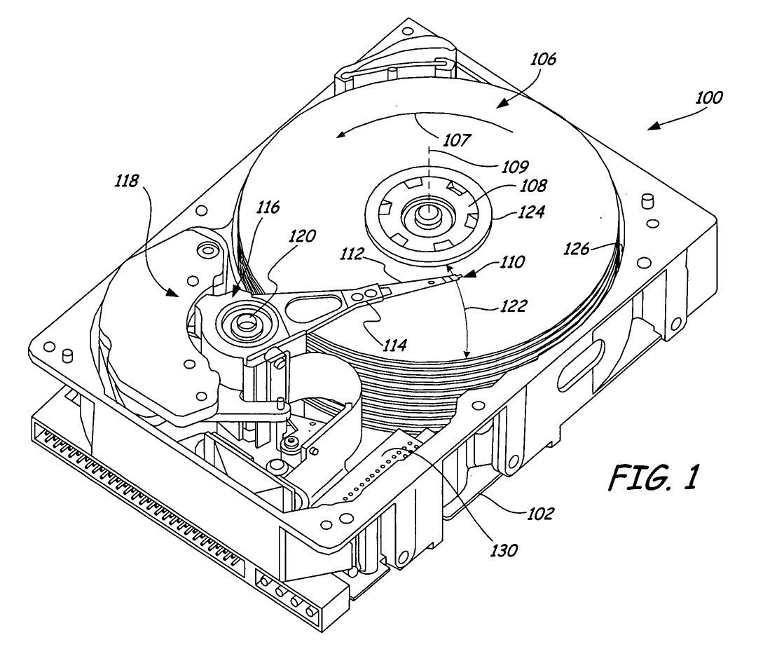

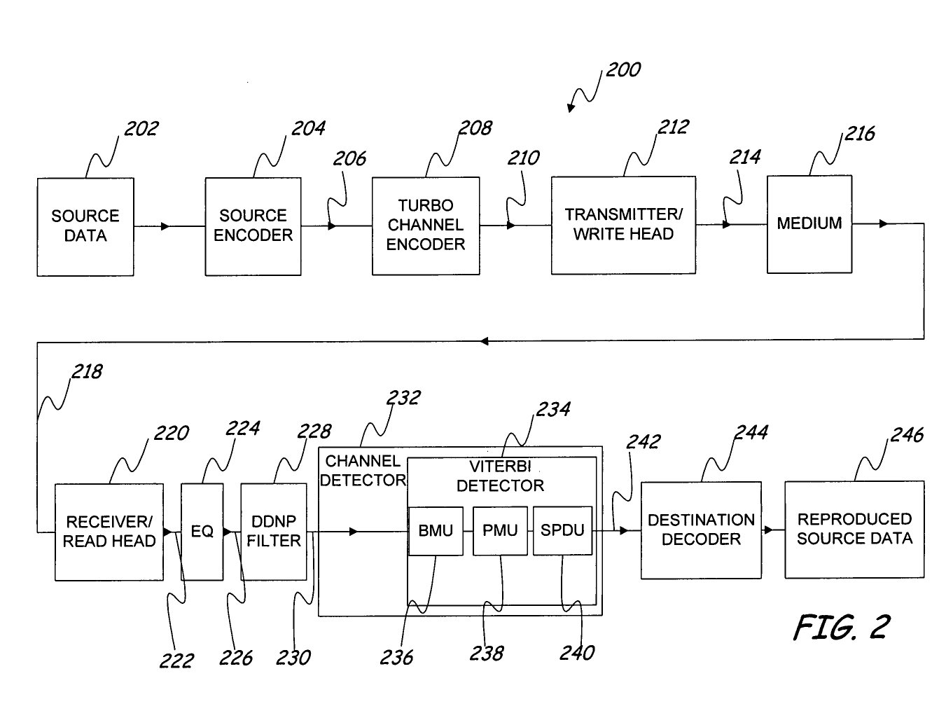

FIG. 1 is an isometric view of a disc drive 100 in which embodiments of the present invention are useful. Disc drive 100 includes a housing with a base 102 and a top cover (not shown). Disc drive 100 further includes a disc pack 106, which is mounted on a spindle motor (not shown) by a disc clamp 108. Disc pack 106 includes a plurality of individual discs, which are mounted for co-rotation in a direction indicated by arrow 107 about central axis 109. Each disc surface has an associated disc head slider 110 which is mounted to disc drive 100 for communication with the disc surface. In the example shown in FIG. 1, sliders 110 are supported by suspensions 112 which are in turn attached to track accessing arms 114 of an actuator 116. The actuator shown in FIG. 1 is of the type known as a rotary moving coil actuator and includes a voice coil motor (VCM), shown generally at 118. Voice coil motor 118 rotates actuator 116 with its attached heads 110 about a pivot shaft 120 to position heads 110 over a desired data track along an arcuate path 122 between a disc inner diameter 124 and a disc outer diameter 126. Voice coil motor 118 is driven by servo electronics 130 based on signals generated by heads 110 and a host computer (not shown). Data stored on disc drive 100 is encoded for writing on the disc pack 106, and then subsequently read from the disc and decoded. The encoding and decoding processes are described in more detail below in connection with an example shown in FIG. 2.

FIG. 2 is a block diagram illustrating the architecture of a read/write channel 200 of a storage device such as the disc drive in FIG. 1 or other communication channel in which data is encoded before transmission through a communication medium, and decoded after communication through the communication medium. In the example of the disc drive, the communication medium comprises a read/write head and a storage medium.

Source data 202, typically provided by a host computer system (not illustrated) is received by a source encoder 204. An output 206 of the source encoder 204 couples to an input of a turbo channel encoder 208. An output 210 of the turbo channel encoder 208 couples to a transducer 212. In the case of a disc drive, the transducer 212 comprises a write head. In communication channels other than a disc drive, the transducer typically comprises a transmitter. An output 214 of the transducer 212 couples to a communication medium 216. In the case of a disc drive, the communication medium 216 comprises a storage surface on a disc. In communication channels other than a disc drive, the communication medium 216 comprises other types of transmission media such as a cable, a transmission line or free space.

The medium 216 communicates data along line 218 to a transducer 220. In the case of a disc drive, the transducer 220 comprises a read head. In the case of other communication channels, the transducer 220 typically comprises a receiver. A equalizer (EQ) 224 receives an output 222 from the transducer 220 and responsively provides an equalized output 226. Equalized output 226 is provided to a filter 228 (for example, a data-dependent-noise-predictive (DDNP) filter) which, in turn, provides a filtered output 230. A channel detector 232 receives the filtered output 230. The channel detector 232 comprises a Viterbi detector 234. Design and operation of Viterbi detector 234 is influenced by a type of filter 228 employed. For example, if filter 228 is a DDNP filter, a DDNP Viterbi detector 234 is employed, which has particular features that are described further below. Viterbi detector 234 includes a branch metric unit (BMU) 236, a path metric unit (PMU) 238 and a survivor path decoding unit (SPDU) 240. As noted earlier, the branch metric unit calculates the branch metrics, which are a measure of the difference between a received symbol and that symbol which causes the corresponding state transition in the trellis diagram. The branch metrics calculated by branch metric unit 236 are supplied to path metric unit 238 in order to determine the optimum paths (survivor paths), with a survivor memory unit (not shown) storing these survivor paths so that, in the end, decoding can be carried out by survivor path decoding unit 240 on the basis of that survivor path which has the best path metric. An output 242 of the survivor path decoding unit 240 couples to a destination decoder 244. The destination decoder 244 provides an output 246 of reproduced source data that typically couples to the host computer system. The various stages of coding and decoding performed in channel 200 help to ensure that the reproduced source data is an accurate reproduction of the source data 202.

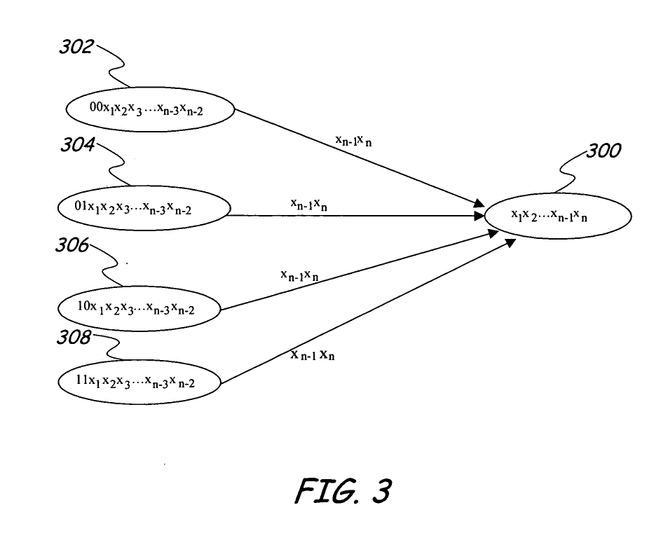

As mentioned above, in conventional path metric units, arithmetic operations (such as add, compare and select operations) are generally sequential in nature, which can lead to processing bottlenecks. In embodiments of the present invention, in the determination of a lowest path-metric among multiple paths that reach a state, at least one of the add units of path metric unit 238 operates in parallel with at least one of its compare units, thereby reducing a critical path in the path metric unit. Example algorithms suitable for carrying out path metric computations in Viterbi detector 234 are described below in connection with Equations 1-21 and FIGS. 3-7.

The example algorithms are described below by first developing an appropriate background and model notation. This is followed by the derivation of path metric computation functions for practical implementation in path metric unit 238 of Viterbi detector 234.

For the following discussion and derivation of the example algorithms, it is assumed that the readback signal (or, in general, output 222 from transducer 220) is equalized to a degree m static target polynomial which, in turn, is followed by a data-dependent-noise-predictive (DDNP) filter of degree (n−m), the resulting overall polynomial thus requiring 2ⁿ states in a Viterbi trellis. It is also assumed that the Viterbi detector is implemented in radix-4 fashion.

FIG. 3 is a diagrammatic illustration of a typical state transition in a radix-4 n-state Viterbi trellis. In the 2ⁿ-state radix-4 trellis shown in FIG. 3, it is observed that a state S with the label ‘x₁x₂x₃ . . . xₙ₋₁xₙ′ (denoted by reference numeral 300) can be arrived at via branches labeled ‘xₙ₋₁xₙ’ from the following four states: 00x₁x₂x₃ . . . xₙ₋₃xₙ₋₂ (denoted by reference numeral 302), 01x₁x₂x₃ . . . xₙ₋₃xₙ₋₂ (denoted by reference numeral 304), 10x₁x₂x₃ . . . xₙ₋₃xₙ₋₂ (denoted by reference numeral 306), 11x₁x₂x₃ . . . xₙ₋₃xₙ₋₂ (denoted by reference numeral 308). For simplification, the four states 302, 304, 306 and 308 from which branches lead to state S (300) are denoted by letters A, B, C and D, and their corresponding state metrics are denoted by S_{A}, S_{B}, S_{C} and S_{D}, respectively. Let L denote the condition length, meaning that every distinct L-bit non-return-to-zero (NRZ) combination in the trellis needs a unique DDNP filter, resulting in 2^{L} total number of filters to compute branch-metrics.

In a half-rate trellis, given a pair of received samples rⱼ and r₍ⱼ₊₁₎, and given the state S to which a branch comes from state A, the branch-metric BM_{A} corresponding to the two NRZ bits xⱼ and xⱼ₊₁ on that branch is given by

$${BM}_{A} = {( {\sum }_{i = 0}^{n - m} {f}_{i}^{[ A 1 ]} {n}_{j - i}^{[ A ]} - {B}_{f}^{[ A 1 ]} )}^{2} + {( {\sum }_{i = 0}^{n - m} {g}_{i}^{[ A 2 ]} {n}_{j + 1 - i}^{[ A ]} - {B}_{g}^{[ A 2 ]} )}^{2} \qquad Equation 1$$

where for 0≦i≦(n−m), fᵢ^{[A1]}, gᵢ^{[A2]} are the taps and B_{f}^{[A1]}, B_{g}^{[A2]} are the biases of the DDNP filters represented by the two NRZ conditions [A1]=(X_{j-L+1}x_{j-L+2} . . . xⱼ) and [A2]=(x_{j-L+2}x_{j-L+3} . . . xⱼ₊₁) respectively; (here, xⱼ₋ₚ=A(n−p+1) for 1≦p≦(L−1), where A(u) denotes the u^{th} bit in the state representation of A;) nⱼ₋ᵢ^{[A]}0≦i≦(n−m) are the noise-samples generated at the output of the front-end target equalizer under the assumption that the transmitted NRZ sequence is Axⱼ, where Axⱼ is the concatenation of the bits in the state-representation of A and xⱼ; nⱼ₊₁₋ᵢ^{[A]}0≦i≦(n−m) are the noise-samples generated at the output of the front-end target equalizer under the assumption that the transmitted NRZ sequence is A(2:n)xⱼxⱼ₊₁, where A(2:n)xⱼxⱼ₊₁ is the concatenation of the last (n−1) bits in the state-representation of A with the NRZ bit string xⱼxⱼ₊₁ on the branch connecting A to S.

Equation 1 can be simplified by rewriting it as follows:

$${BM}_{A} = {( {\sum }_{i = 0}^{n - m} {f}_{i}^{[ A 1 ]} ( {r}_{j - i} - {t}_{j - i}^{[ A ]} ) - {B}_{f}^{[ A 1 ]} )}^{2} + {( {\sum }_{i = 0}^{n - m} {g}_{i}^{[ A 2 ]} ( {r}_{j + 1 - i} - {t}_{j + 1 - i}^{[ A ]} ) - {B}_{g}^{[ A 2 ]} )}^{2} \qquad Equation 2$$

In Equation 2 above, tⱼ₋ᵢ^{[A]}0≦i≦(n−m) are the ideal-samples generated at the output of a front-end target equalizer (not shown) under the assumption that the transmitted NRZ sequence is Axⱼ, where Axⱼ is the concatenation of the bits in the state-representation of A and xⱼ; tⱼ₊₁₋ᵢ^{[A]}0≦i≦(n−m) are the ideal-samples generated at the output of the front-end target equalizer under the assumption that the transmitted NRZ sequence is A(2:n)xⱼxⱼ₊₁, where A(2:n)xⱼxⱼ₊₁ is the concatenation of the last (n−1) bits in the state-representation of A with the NRZ bit string xⱼxⱼ₊₁ on the branch connecting A to S; rⱼ₋₁, 0≦i≦(n−m) are the received samples at the output of the front-end equalizer.

Equation 2 can be rewritten as follows:

$${BM}_{A} = {( {\sum }_{i = 0}^{n - m} {f}_{i}^{[ A 1 ]} {r}_{j - i} - {\sum }_{i = 0}^{n - m} {f}_{i}^{[ A 1 ]} {t}_{j - i}^{[ A ]} - {B}_{f}^{[ A 1 ]} )}^{2} + {( {\sum }_{i = 0}^{n - m} {g}_{i}^{[ A 2 ]} {r}_{j + 1 - i} - {\sum }_{i = 0}^{n - m} {g}_{i}^{[ A 2 ]} {t}_{j + 1 - i}^{[ A ]} - {B}_{g}^{[ A 2 ]} )}^{2} \qquad Equation 3$$

For simplification, the following notations are used:

$$\begin{matrix}{Q}_{j}^{[ A 1 ]} = {\sum }_{i = 0}^{n - m} {F}_{i}^{[ A 1 ]} {t}_{j - i}^{[ A ]} + {B}_{f}^{[ A 1 ]} \\ and & Equation 4 \\ {Q}_{j + 1}^{[ A 2 ]} = {\sum }_{i = 0}^{n - m} {g}_{i}^{[ A 2 ]} {t}_{j + 1 - i}^{[ A ]} + {B}_{g}^{[ A 2 ]} \\ In Equation 4 , & Equation 5 \\ {t}_{j - i}^{[ A ]} = {\sum }_{p = 0}^{m} {k}_{p} {x}_{j - i - p}^{[ A ]} & Equation 6\end{matrix}$$

where kₚ are the coefficients of the degree m polynomial given by

$${\sum }_{p = 0}^{m} {k}_{p} {D}^{p} .$$

Here, D is a unit-delay operator used in defining filter polynomials. Similarly, in Equation 5,

$${t}_{j + 1 - i}^{[ A ]} = {\sum }_{p = 0}^{m} {k}_{p} {x}_{j + 1 - i - p}^{[ A ]} \qquad Equation 7$$

where xⱼ₊₁₋ᵢ₋ₚ=A(n−i−p) for 1≦i≦(n−m). Substituting Equation 6 in Equation 4 and Equation 7 in Equation 5, the following are obtained:

$$\begin{matrix}{Q}_{j}^{[ A ]} = {\sum }_{i = 0}^{n - m} {\sum }_{p = 0}^{m} {f}_{i}^{[ A 1 ]} {k}_{p} {x}_{j - i - p}^{[ A ]} & Equation 8 \\ {Q}_{j + 1}^{[ A 2 ]} = {\sum }_{i = 0}^{n - m} {\sum }_{p = 0}^{m} {g}_{i}^{[ A 2 ]} {k}_{p} {x}_{j + 1 - i - p}^{[ A ]} + {B}_{g}^{[ A 2 ]} & Equation 9\end{matrix}$$

By using identical reasoning and notation for the other three states (B, C and D) from which branches also go to state S, the following four candidate path metrics, PM₁, PM₂, PM₃ and PM₄, for the four paths that end at state S, form the four Add-Compare-Select (ACS) update equations shown below:

$$\begin{matrix}{PM}_{1} = [ \begin{matrix}{S}_{A} + {( {\sum }_{i = 0}^{n - m} {f}_{i}^{[ A 1 ]} {r}_{j - i} - {Q}_{j}^{[ A 1 ]} )}^{2} + \\ {( {\sum }_{i = 0}^{n - m} {g}_{i}^{[ A 2 ]} {r}_{j + 1 - i} - {Q}_{j + 1}^{[ A 2 ]} )}^{2}\end{matrix} ] & Equation 10 \\ {PM}_{2} = [ \begin{matrix}{S}_{B} + {( {\sum }_{i = 0}^{n - m} {f}_{i}^{[ B 1 ]} {r}_{j - i} - {Q}_{j}^{[ B 1 ]} )}^{2} + \\ {( {\sum }_{i = 0}^{n - m} {g}_{i}^{[ B 2 ]} {r}_{j + 1 - i} - {Q}_{j + 1}^{[ B 2 ]} )}^{2}\end{matrix} ] & Equation 11 \\ {PM}_{3} = [ \begin{matrix}{S}_{C} + {( {\sum }_{i = 0}^{n - m} {f}_{i}^{[ C 1 ]} {r}_{j - i} - {Q}_{j}^{[ C 1 ]} )}^{2} + \\ {( {\sum }_{i = 0}^{n - m} {g}_{i}^{[ C 2 ]} {r}_{j + 1 - i} - {Q}_{j + 1}^{[ C 2 ]} )}^{2}\end{matrix} ] & Equation 12 \\ {PM}_{4} = [ \begin{matrix}{S}_{D} + {( {\sum }_{i = 0}^{n - m} {f}_{i}^{[ D 1 ]} {r}_{j - i} - {Q}_{j}^{[ D 1 ]} )}^{2} + \\ {( {\sum }_{i = 0}^{n - m} {g}_{i}^{[ D 2 ]} {r}_{j + 1 - i} - {Q}_{j + 1}^{[ D 2 ]} )}^{2}\end{matrix} ] & Equation 13\end{matrix}$$

Observations

1. All the Q's in the above equations can be pre-computed as they do not depend on received samples.

2. Qⱼ₊₁^{[A2]}=Qⱼ₊₁^{[C2]}and Qⱼ₊₁^{[B2]}=Qⱼ₊₁^{[D2]} if L≦n. (This Observation is independent of a front-end target and its length, and DDNP filter-lengths. It is simply a consequence of a second bit in states A and C being the same, and a second bit in states B and D being the same.)

3. Qⱼ^{[A1]}, Qⱼ^{[B1]}, Qⱼ^{[C1]}, Qⱼ^{[D1]} are distinct from each other. (This Observation is independent of a front-end target and its length, DDNP filter-length, and condition length. It is simply a consequence of, when taken together, the first two bits in the originating states A, B, C and D being different for all the states.)

4. If L≦n, gᵢ^{[A2]}=gᵢ^{[B2]}=gᵢ^{[C2]}=gᵢ^{[D2]}∀i≦(n−m). In other words, all these filters will be identical since the NRZ conditions [A2], [B2], [C2] and [D2] that define the filters are identical. This makes the second squared-quantity in Equation 10 and Equation 12 identical, and also makes the second squared-quantity in Equation 11 and Equation 13 identical. Additionally, this condition also makes fᵢ^{[A1]}=fᵢ^{[C1]} and fᵢ^{[B1]}=fᵢ^{[D1]}∀i≦(n−m).

5. If L≦(n−1), fᵢ^{[A1]}=fᵢ^{[B1]}=fᵢ^{[C1]}=fᵢ^{[D1]}∀i≦(n−m). In other words, all these filters will be identical since the NRZ conditions [A1], [B1], [C1] and [D1], that define the filters, are identical.

Consequences for Circuit Implementation

It is assumed that L≦n; Observation 4 then holds true. This particular Observation has implications for reducing the critical path of the ACS in the path metric unit. Under this assumption, Equation 10 through Equation 13 can be re-written as:

$$\begin{matrix}{PM}_{1} = [ {S}_{A} + {( {\sum }_{i = 0}^{n - m} {f}_{i}^{[ A 1 C 1 ]} {r}_{j - i} - {Q}_{j}^{[ A 1 ]} )}^{2} + {Q}_{j + 1}^{[ AC ]} ] & Equation 14 \\ {PM}_{2} = [ {S}_{B} + {( {\sum }_{i = 0}^{n - m} {f}_{i}^{[ B 1 D 1 ]} {r}_{j - i} - {Q}_{j}^{[ B 1 ]} )}^{2} + {Q}_{j + 1}^{[ B D ]} ] & Equation 15 \\ {PM}_{3} = [ {S}_{C} + {( {\sum }_{i = 0}^{n - m} {f}_{i}^{[ A 1 C 1 ]} {r}_{j - i} - {Q}_{j}^{[ C 1 ]} )}^{2} + {Q}_{j + 1}^{[ AC ]} ] & Equation 16 \\ {PM}_{4} = [ {S}_{D} + {( {\sum }_{i = 0}^{n - m} {f}_{i}^{[ B 1 D 1 ]} {r}_{j - i} - {Q}_{j}^{[ D 1 ]} )}^{2} + {Q}_{j + 1}^{[ B D ]} ] & Equation 17\end{matrix}$$

In the above equations, the dependence of Qⱼ₊₁ is denoted on the originating state, and the sameness of that dependence for two different originating states, by writing those two common originating states in the superscript on Qⱼ₊₁ terms. Similar notation is used for filter-taps. However, since Qⱼ terms are all different, the branch-metrics for the rⱼ terms will differ from each other in the above equations. To denote this, the notation is further modified as shown below:

$$\begin{matrix}{PM}_{1} = [ {S}_{A} + {Q}_{j}^{[ A ]} + {Q}_{j + 1}^{[ AC ]} ] & Equation 18 \\ {PM}_{2} = [ {S}_{B} + {Q}_{j}^{[ B ]} + {Q}_{j + 1}^{[ B D ]} ] & Equation 19 \\ {PM}_{3} = [ {S}_{C} + {Q}_{j}^{[ C ]} + {Q}_{j + 1}^{[ AC ]} ] & Equation 20 \\ {PM}_{4} = [ {S}_{D} + {Q}_{j}^{[ D ]} + {Q}_{j + 1}^{[ B D ]} ] & Equation 21\end{matrix}$$

In Equations 18 through 21, the S terms are state metrics, the Qⱼ terms are radix-2 branch metrics computed at sample rⱼ, and the Qⱼ₊₁ terms are radix-2 branch metrics computed at sample rⱼ₊₁. Qⱼ terms and Qⱼ₊₁ terms are referred to herein as first branch metrics and second branch metrics, respectively. It is assumed that the individual terms in Equations 18 through 21 were computed beforehand and are thus available. A relatively straightforward ACS operation, within the path metric unit, would involve the following four operations in picking a winner (i.e., the path with the lowest path-metric) among the four paths that reach S.
Normal Operation

1. First, in parallel, carry out a first Addition (addition of state metrics to the first branch metrics) in equations 18 through 21.

2. Next, in parallel, carry out a second Addition (addition of the second branch metrics to the quantities obtained in step 1) in equations 18 through 21.

3. Next, in parallel, Compare (PM₁, PM₂) and (PM₃, PM₄) and obtain the winners of these comparisons. (The smaller of the two numbers is the winner.) Denote the winners by W₁ and W₂, respectively.

4. Finally, Compare W₁ and W₂. The result of this comparison is the winning path metric, and this becomes the updated state-metric for state S.

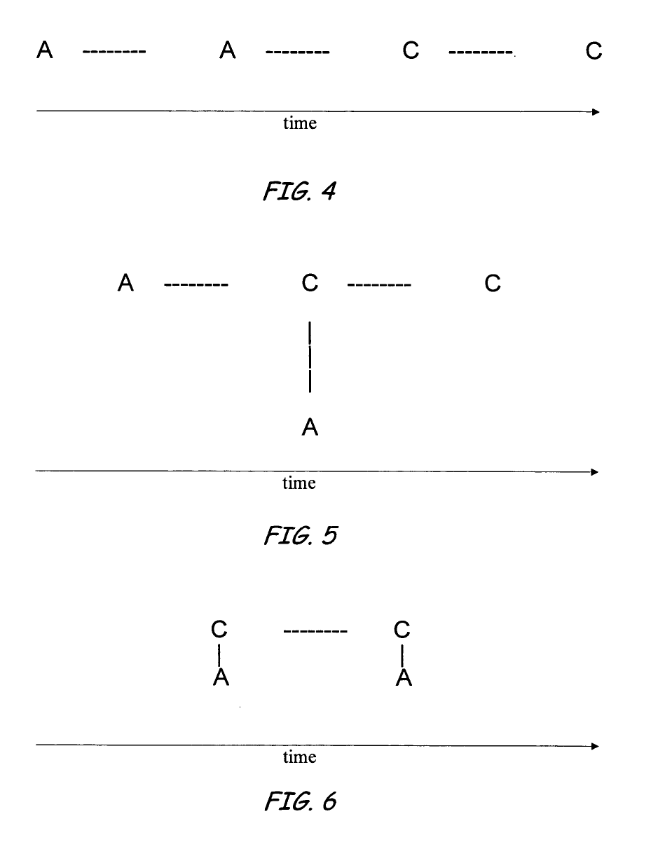

Therefore, along a time axis, an Add-Add-Compare-Compare needs to be carried out in the path metric unit. This is the critical path in the path metric unit. This path is represented diagrammatically, along a time axis, in FIG. 4 in which an addition is denoted by A and a comparison is denoted by C. The same notation is used for additions and comparisons in FIGS. 5 and 6, which are described further below.

By making use of Observation 4, two algorithms are proposed that can shorten the critical path shown in FIG. 4. The algorithms are as follows:

Algorithm 1

1. First, in parallel, carry out the first Addition in equations 18 through 21 and obtain four intermediate results R₀, R₁, R₂ and R₃. These four intermediate results are referred to herein as partial path metrics.

2. Next, in parallel, Compare (R₀, R₂) and (R₁, R₃) and obtain the winners. While carrying out this comparison, in parallel, Add Qⱼ₊₁^{[AC]} to both R₀ and R₂ and Qⱼ₊₁^{[BD]} to both R₁ and R₃. So, by the time the winners of the comparisons are available, Qⱼ₊₁^{[AC]} and Qⱼ₊₁^{[BD]} will have been added to the winners already. Denote these two numbers by W₁ and W₂.

3. Finally, Compare W₁ and W₂ to obtain a winning path metric, which becomes the updated state-metric for state S.

Note that in this method, along the time-axis, the critical path includes only Add-Compare-Compare, contributing to a shortening of the critical path by 25% and hence a speedup of the ACS by a factor of (4/3). Note that when carrying out the second Compare in the chain, the Addition is being carried out in parallel. Thus, the critical path can be represented diagrammatically as shown in FIG. 5.

Algorithm 2

1. R₀, R₁, R₂ and R₃ are already available. (It will become clear in step 2 as to why this is true.). Therefore, in parallel, Compare (R₀, R₂) and (R₁, R₃) and obtain the winners. While carrying out this comparison, in parallel, Add Qⱼ₊₁^{[AC]} to both R₀ and R₂ and Qⱼ₊₁^{[BD]} to both R₁ and R₃. So, by the time the winners of the comparisons are available, Qⱼ₊₁^{[AC]} and Qⱼ₊₁^{[BD]} will have been added to the winners. Denote these two numbers by W₁ and W₂.

2. Compare W₁ and W₂ to obtain the winning path metric and that becomes the updated state-metric for state S. While carrying out this comparison, in parallel, compute W₁+Qⱼ₊₂^{[0]}, W₁+Qⱼ₊₂^{[1]} and W₂+Qⱼ₊₂^{[0]}, W₂+Qⱼ₊₂^{[1]}. Here, Qⱼ₊₂^{[0]} is the branch-metric of rⱼ₊₂ computed for NRZ bit 0, and Qⱼ₊₂^{[1]} is the branch-metric of rⱼ₊₂ computed for NRZ bit 1. (If W₁ wins, additions to W₂ will be discarded and if W₂ wins, additions to W₁ will be discarded.) The results of these retained additions, R^{[0,S]} and R^{[1,5]}, will form R₀, R₁, R₂, and R₃ for subsequent states in the next clock-cycle as shown below in Table 1.

TABLE 1

| | | |
|---|---|---|
| S = X₁X₂ . . . Xₙ | For Next State = | For Next State = |

| X₁ | X₂ | (X₃X₄ . . . 0Xₙ₊₂) | (X₃X₄ . . . 1Xₙ₊₂) |
|---|---|---|---|
| 0 | 0 | R₀ = R^{[0]} | R₀ = R^{[1]} |
| 0 | 1 | R₁ = R^{[0]} | R₁ = R^{[1]} |
| 1 | 0 | R₂ = R^{[0]} | R₂ = R^{[1]} |
| 1 | 1 | R₃ = R^{[0]} | R₃ = R^{[1]} |

From Column 3 of Table 1 it is observed that the two next states (X₃X₄ . . . 00) and (X₃X₄ . . . 01) will have the same Rᵢ value as their input, namely R^{[0]}. Here i is the decimal equivalent of the binary double X₁X₂. (It is also noted that if T is the decimal representation of the state (X₃X₄ . . . 00), then (T+1) will be the decimal representation of the state (X₃X₄. . . 01).) Another observation from Column 4 of Table 1 is that states with decimal equivalents (T+2) and (T+3) share the same Rᵢ value, namely R^{[1]}. The above statements are summarized in Observation 6 below:
Observation 6

In the half-rate implementation of a DDNP SOVA with 2ⁿ states, each state S with binary representation (X₁X₂ . . . Xₙ₋₁Xₙ) will generate Rᵢ inputs of Algorithm 2 for four states in the next clock-cycle: T, T+1, T+2, and T+3, where T is the decimal equivalent of the state (X₃X₄ . . . 00) and i is the decimal equivalent of the binary double X₁X₂. Only two of these four Rᵢ values will be distinct: the states T and (T+1) will share one Rᵢ value R^{[0,S]} and states (T+2) and (T+3) will share the other value R^{[0,S]}.

A specific instance of Observation 6 for a 16-state trellis is given in Table 2 below. In this table, for each state S, R^{[0,S]}=S+Qⱼ₊₂^{[0]} and R^{[1,S]}=S+Qⱼ₊₂^{[1]}. (Here S is interchangeably used both to denote the label of the state S and its state-metric value.)

TABLE 2

| Decimal | | | | |
|---|---|---|---|---|
| Equivalent of | | | | |
| State = | | | | |
| (X₃X₄ . . . Xₙ₊₁Xₙ₊₂) | R₀ | R₁ | R₂ | R₃ |
| 0 = 0000 | R^{[0,0000]} | R^{[0,0100]} | R^{[0,1000]} | R^{[0,1100]} |
| 1 = 0001 | | | | |
| 2 = 0010 | R^{[1,0000]} | R^{[1,0100]} | R^{[1,1000]} | R^{[1,1100]} |
| 3 = 0011 | | | | |
| 4 = 0100 | R^{[0,0001]} | R^{[0,0101]} | R^{[0,1001]} | R^{[0,1101]} |
| 5 = 0101 | | | | |
| 6 = 0110 | R^{[1,0001]} | R^{[1,0101]} | R^{[1,1001]} | R^{[1,1101]} |
| 7 = 0111 | | | | |
| 8 = 1000 | R^{[0,0010]} | R^{[0,0110]} | R^{[0,1010]} | R^{[0,1110]} |
| 9 = 1001 | | | | |
| 10 = 1010 | R^{[1,0010]} | R^{[1,0110]} | R^{[1,1010]} | R^{[1,1110]} |
| 11 = 1011 | | | | |
| 12 = 1100 | R^{[0,0011]} | R^{[0,0111]} | R^{[0,1011]} | R^{[0,1111]} |
| 13 = 1101 | | | | |
| 14 = 1110 | R^{[1,0011]} | R^{[1,0111]} | R^{[1,1011]} | R^{[0,1111]} |
| 15 = 1111 | | | | |

Note that, in the method according to Algorithm 2, along the time-axis, the critical path includes only Compare-Compare, contributing to a shortening of the path by 50% when compared to Normal Operation and hence a speedup of the ACS by a factor of 2. Additions are being carried out in parallel while carrying out the Comparisons and therefore the ACS path can be represented diagrammatically as shown in FIG. 6.

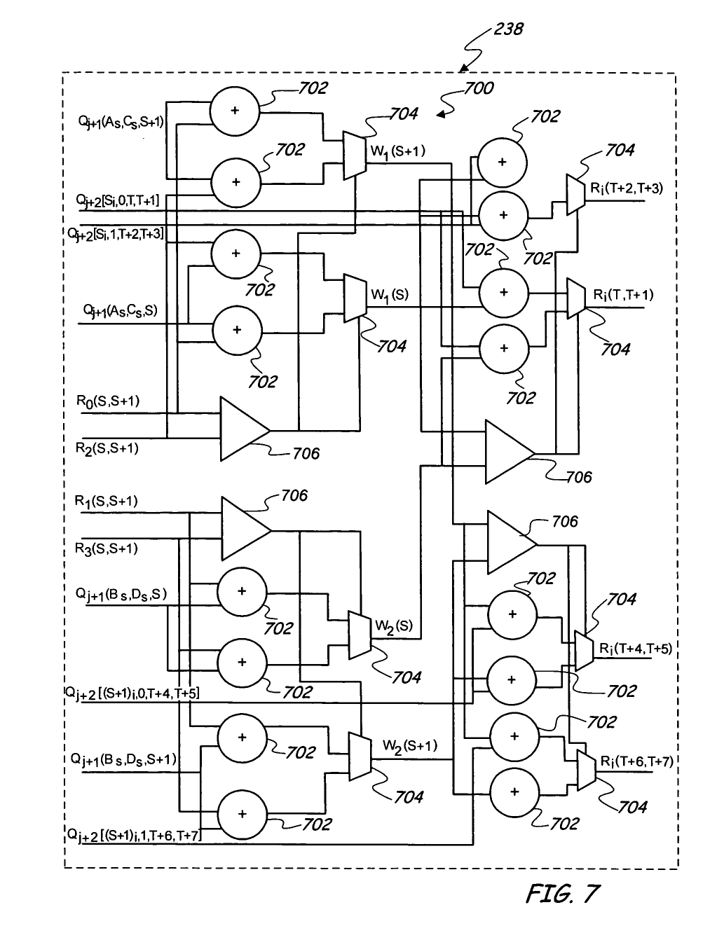

FIG. 7 illustrates an example building block 700 of a path metric unit (such as 238) for a half-rate (radix-4 or two samples per clock cycle) implementation of a DDNP Viterbi trellis. Block 700 includes multiple add units 702, multiple compare units 704 and clock signal generation units 706, which are coupled together in the example arrangement shown in FIG. 7. Components 702, 704 and 706 may be hardware, software or firmware modules/units. In block 700, results of comparisons of (R₀, R₂) and (R₁, R₃) for two adjacent states S and (S+1) are shared. To facilitate this, block 700 takes the inputs necessary for updating the state-metrics of both the states and outputs the four Rᵢ terms for the following clock-cycle generated by both the states S and (S+1).

The following notation is used in FIG. 7:
S is assumed to be a state with an even integer as its decimal equivalent.
Rᵢ(S, S+1) is a common Rᵢ value used for the states S and (S+1) for i=0, 1, 2, 3.
Qⱼ₊₁(Aₛ, Cₛ, S) is a common radix-2 branch-metric of sample r₊₁ coming to state S from States A and C. (State A starts with the binary double 00 and State C starts with the binary double 10.)
Qⱼ₊₁(Bₛ, Dₛ, S) is a common radix-2 branch-metric of sample rⱼ₊₁ coming to state S from States B and D. (State B starts with the binary double 01 and State D starts with the binary double 11.)
Qⱼ₊₂ (i, 0, T, T+1) is a radix-2 branch-metric computed for sample rⱼ₊₂ for the branch connecting states S and T for the NRZ bit 0. Here i is the decimal equivalent of the binary double X₁X₂ where S=(X₁X₂ . . . Xₙ) and T is the decimal equivalent of (X₃X₄ . . . 00) and (T+1) is the decimal equivalent of (X₃X₄ . . . 01).
Qⱼ₊₂ (i, 1, T, T+1) is a radix-2 branch-metric computed for sample rⱼ₊₂ for the branch connecting states S and T for the NRZ bit 1. Here, i is the decimal equivalent of the binary double X₁X₂ where S=(X₁X₂ . . . Xₙ) and T is the decimal equivalent of (X₃X₄ . . . 10) and (T+1) is the decimal equivalent of (X₃X₄ . . . 11).
Rᵢ(T, T+1) is a common Rᵢ value generated for states T and (T+1) for a next clock-cycle.

As noted earlier, a normal radix-4 Viterbi detector implementation involves a sequence of 4 operations: Add, Add, Compare, Compare. If it takes ‘t’ time units to perform an Add or Compare operation, then the total time spent in the critical path is 4t for a radix-4 operation. The Algorithm 2 Viterbi detector implementation described above, in connection with FIGS. 6 and 7, performs comparisons and additions in parallel, thus reducing the critical path time to 2t. This enables the Algorithm 2 Viterbi detector to potentially run at twice the speed when compared to normal operation.

The present invention provides parallization of arithmetic operations at an algorithm level as opposed to bit or word level parallelization. Although the above embodiments of the present invention are directed to a radix-4 (two samples per clock cycle) Viterbi detector, the teachings of the present invention are, in general, applicable to a radix-2ⁿ Viterbi detector, where n is a positive integer.

It is to be understood that even though numerous characteristics and advantages of various embodiments of the invention have been set forth in the foregoing description, together with details of the structure and function of various embodiments of the invention, this disclosure is illustrative only, and changes may be made in detail, especially in matters of structure and arrangement of parts within the principles of the present invention to the full extent indicated by the broad general meaning of the terms in which the appended claims are expressed. For example, the particular elements may vary depending on the particular application for the communication channel while maintaining substantially the same functionality without departing from the scope and spirit of the present invention. In addition, although the preferred embodiment described herein is directed to a read/write channel for a data storage device, it will be appreciated by those skilled in the art that the teachings of the present invention can be applied to other communication channels, without departing from the scope and spirit of the present invention.

What is claimed is:

1. A data detector comprising:
a path metric unit, configured to operate at a rate of at least two samples
per clock cycle, comprising:
a plurality of add units; and
a plurality of compare units,
wherein, in the determination of a lowest path-metric among multiple paths that reach a state, at least one of the plurality of add units operates in parallel with at least one of the plurality of compare units, thereby reducing a critical path in the path metric unit.

2. The apparatus of claim 1 wherein at least one of the plurality of add units is configured to operate in series with at least one of the corresponding plurality of compare units.

3. The apparatus of claim 1 wherein substantially all of the plurality of add units are configured to operate in parallel with substantially all of the corresponding plurality of compare units.

4. A data storage device comprising the data detector of claim 1.

5. The apparatus of claim 4 wherein the data storage device is a disc drive.

6. The apparatus of claim 1 wherein the data detector is a soft output Viterbi algorithm (SOVA) detector.

7. The apparatus of claim 1 wherein the data detector is a data-dependent-noise-predictive (DDNP) soft output Viterbi algorithm (SOVA) detector.

8. The apparatus of claim 1 and further comprising a branch metric unit which receives a transducer output and responsively provides branch metrics to the path metric unit, which, in turn, provides the lowest path-metric among multiple paths that reach a state.

9. The apparatus of claim 8 and further comprising a survivor path decoding unit, which is configured to decode the lowest path metric output by the path metric unit.

10. A method comprising:
receiving a transducer output;
computing branch metrics for the transducer output;
computing a lowest path metric to reach a state based on at least some of the computed branch metrics,
wherein at least one of a plurality of addition operations and at least one of a plurality of comparison operations carried out to compute the lowest path metric take place in parallel.

11. The method of claim 10 wherein at least one of the plurality of addition operations and at least one of the plurality of comparison operations carried out to compute the lowest path metric take place in series.

12. The method of claim 10 wherein substantially all of the plurality of addition operations and substantially all of the corresponding plurality of comparison operations carried out to compute the lowest path metric take place in parallel.

13. The method of claim 10 wherein a first set of the plurality of arithmetic operations comprises adding state metrics to first branch metrics to obtain partial path metrics.

14. The method of claim 13 wherein a second set of the plurality of arithmetic operations comprises comparing individual partial path metrics to obtain winning partial path metrics and substantially concurrently adding second branch metrics to individual partial path metrics.

15. A channel comprising:
a branch metric unit; and
means for carrying out arithmetic operations to determine a lowest path metric among multiple paths that reach a state, from at least some of a plurality of branch metrics output by the branch metric unit, wherein at least some of the arithmetic operations are carried out in parallel.

16. The apparatus of claim 15 and further comprising a survivor path decoding unit, which is configured to decode the lowest path metric.

17. The apparatus of claim 16 and further comprising a DDNP filter that is configured to provide a filtered output to the branch metric unit.

18. The apparatus of claim 17 and further comprising an equalizer that is configured to receive a transducer output and to provide an equalized output to the DDNP filter.

19. The apparatus of claim 15 wherein a first set of the arithmetic operations comprises adding state metrics to first branch metrics to obtain partial path metrics.

20. The apparatus of claim 19 wherein a second set of the arithmetic operations comprises comparing individual partial path metrics to obtain winning partial path metrics and substantially concurrently adding second branch metrics to individual partial path metrics.
